(19) United States
(12) Patent Application Publication
(10) Pub. No.: US 2024/0296879 A1
(43) Pub. Date: Sep. 5, 2024

(54) DATA INTEGRITY IMPROVEMENT PROGRAMMING TECHNIQUES

(71) Applicant: Micron Technology, Inc., Boise, ID (US)

(72) Inventors: Christopher Joseph Bueb, Folsom, CA (US); Zheng Wang, Louisville, CO (US)

(21) Appl. No.: 18/404,587

(22) Filed: Jan. 4, 2024

Related U.S. Application Data
(60) Provisional application No. 63/439,029, filed on Jan. 13, 2023.

(51) Int. Cl. G11C 11/406; G11C 11/4096; G11C 29/52

(52) U.S. Cl. CPC G11C 11/40618; G11C 11/40626; G11C 11/4096; G11C 29/52

(57) ABSTRACT

Methods, systems, and devices for data integrity improvement programming techniques are described. A memory system may be pre-programed with data prior to assembling the memory system, where assembling the memory system may adversely affect data integrity of a portion of the data. The data integrity of the portion of the data may be improved by programming additional data to the memory system or adjusting data characteristics associated with the portion of the data. The memory system may perform a start-up procedure in which the memory system may identify an indication to perform a refresh operation. The memory system may perform a refresh operation using the additional data programmed to the memory system or using the adjusted data characteristics to improve the data integrity of the portion of the data and mitigate performance issues otherwise associated with performing the refresh operation.

### CROSS REFERENCE

The present Application for Patent claims priority to U.S. Patent Application No. 63/439,029 by Bueb et al., entitled “DATA INTEGRITY IMPROVEMENT PROGRAMMING TECHNIQUES,” filed Jan. 13, 2023, which is assigned to the assignee hereof, and which is expressly incorporated by reference herein.

### FIELD OF TECHNOLOGY

The following relates to one or more systems for memory, including data integrity improvement programming techniques.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports data integrity improvement programming techniques in accordance with examples as disclosed herein.

FIG. 2 illustrates an example of a system that supports data integrity improvement programming techniques in accordance with examples as disclosed herein.

FIG. 3 illustrates an example of a system that supports data integrity improvement programming techniques in accordance with examples as disclosed herein.

FIG. 4 illustrates an example of a process flow that supports data integrity improvement programming techniques in accordance with examples as disclosed herein.

FIG. 5 shows a block diagram of a memory system that supports data integrity improvement programming techniques in accordance with examples as disclosed herein.

FIGS. 6 and 7 show flowcharts illustrating a method or methods that support data integrity improvement programming techniques in accordance with examples as disclosed herein.

### DETAILED DESCRIPTION

In some cases, data (e.g., user data) may be programmed (e.g., written) into a memory system, such that the memory system may support operation of a system or product. For example, the data may be programmed (e.g., preprogrammed) to the memory system before the memory system is assembled into the system or product. During the assembly process the memory system may be exposed to relatively high temperatures (e.g., a reflow soldering process). The relatively high temperatures associated with performing the assembly process may adversely affect data retention (e.g., the ability of the memory system to retain the data that was programmed prior to the assembly process) of a portion of the memory system (e.g., portions most affected by the relatively high temperatures), causing reduced read performance and reduced data integrity for a portion of the data (e.g., stored in the portion of the memory system with adversely affected data retention). In some implementations, a weak geometric layout of word lines associated with accessing the portion of the data may increase the adverse effects of the assembly process on the portion of the data, thereby further reducing the data integrity of the portion of the data. In some implementations, the data may be refreshed after the system is assembled and shipped to a customer (e.g., an in-field refresh). In some cases, the duration (e.g., the delay) between assembling the memory system and refreshing the data may exacerbate the adverse effect on the data retention, causing further reduced read performance and further reduced data integrity. In other implementations, the data may be refreshed immediately after the memory system is assembled with the system or product (e.g., in-factory refresh), yet the timing of refreshing the data (e.g., refreshing the data immediately after assembly) may increase manufacturing time and associated costs.

In accordance with examples as described herein, data integrity improvement programming techniques may be applied to a memory system to improve data integrity of a portion of data otherwise associated with reduced data integrity. For example, data (e.g., user data, first data) may be programmed (e.g., preprogrammed) to the memory system and the portion of the data associated with reduced data integrity (e.g., due to assembling a portion of the memory system with high temperature processes, due to a geometric layout of word lines associated with accessing the portion of the data) may be identified. In some implementations, additional data (e.g., second data) may be programmed to the memory system to improve the data integrity of the portion of the data, where the additional data may be a back-up copy of the data or parity information (e.g., parity bits) associated with the data. In other implementations, data characteristics associated with refreshing the data may be adjusted to improve the data integrity of the portion of the data. For example, adjusting the data characteristics may include identifying and storing adjusted read thresholds (e.g., read trims) or performing a programming operation to adjust voltage threshold levels. After programming the additional data or adjusting the data characteristics, the memory system may perform a refresh operation using the additional data or the adjusted data characteristics to improve the data integrity of the data. The methods and apparatus described herein may be associated with mitigating adverse effects associated with refreshing the data of the memory system after the memory system is assembled, or with the geometric layout of word lines associated with accessing the data, thereby improving the data integrity of the data.

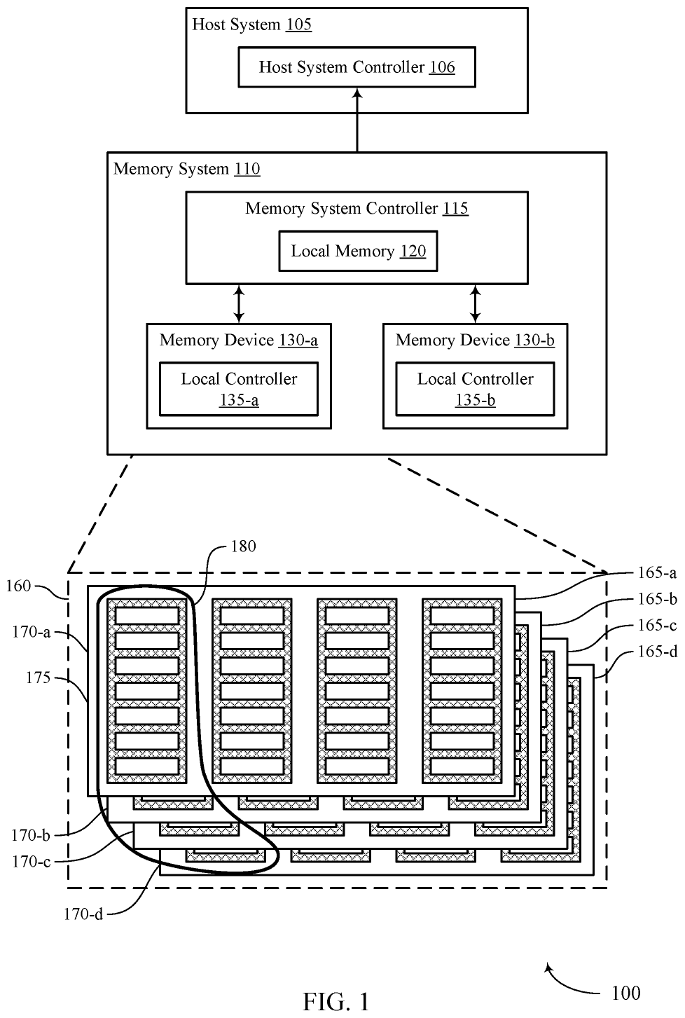

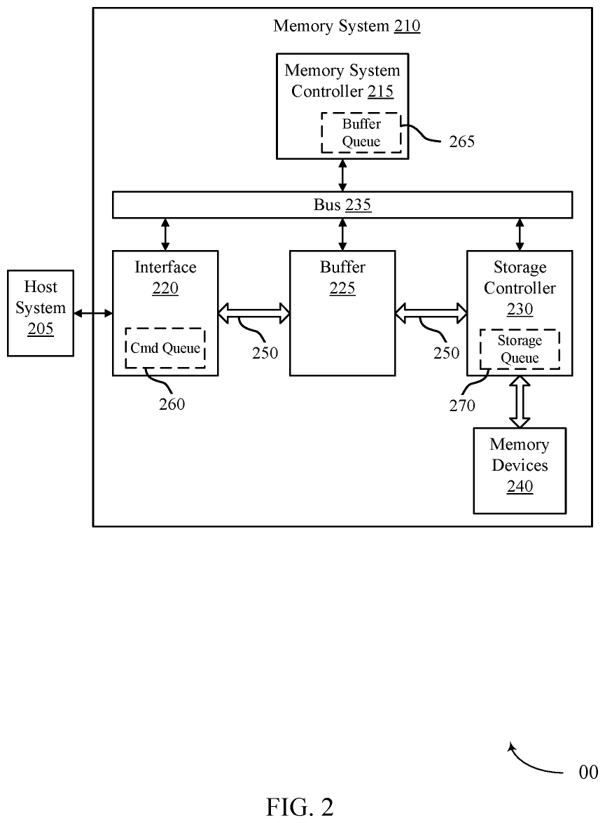

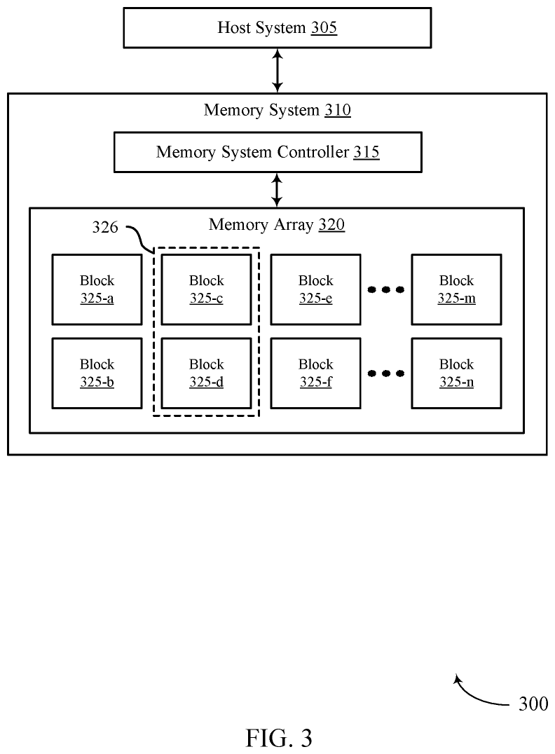

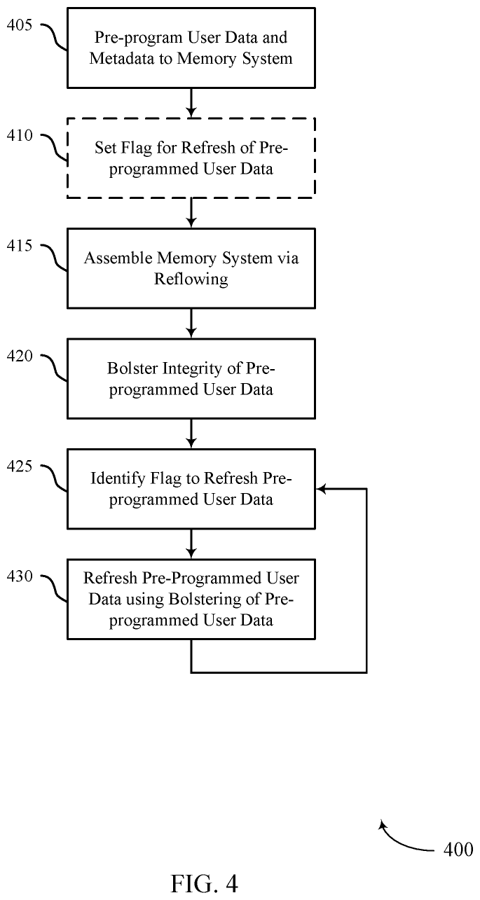

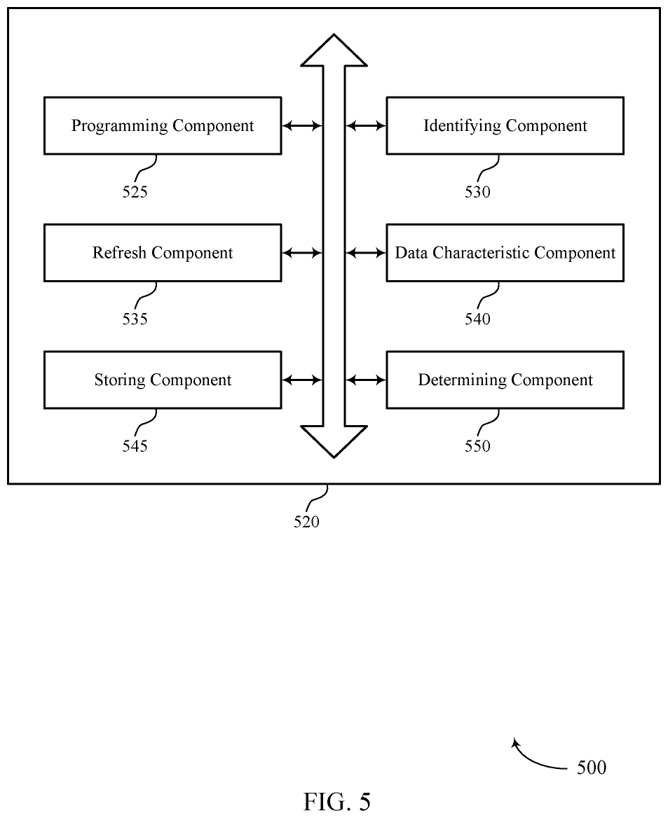

Features of the disclosure are initially described in the context of systems and devices with reference to FIGS. 1 and 2. Features of the disclosure are described in the context of a system and process flow with reference to FIGS. 3 and 4. These and other features of the disclosure are further illustrated by and described in the context of an apparatus diagram and flowchart that relate to data integrity improvement programming techniques with reference to FIGS. 5 through 7.

FIG. 1 illustrates an example of a system 100 that supports data integrity improvement programming techniques in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support data integrity improvement programming techniques. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In accordance with examples as described herein, data integrity improvement programming techniques may be applied to the memory system 110 to improve data integrity of a portion of data otherwise associated with reduced data integrity. For example, data may be programmed to the memory system 110 and the portion of the data associated with reduced data integrity may be identified. In some implementations, additional data may be programmed to the memory system 110 to improve the data integrity of the portion of the data. In other implementations, data characteristics associated with refreshing the data (e.g., read thresholds, voltage threshold levels) may be adjusted to improve the data integrity of the portion of the data. After programming the additional data or adjusting the data characteristics, the memory system 110 may perform a refresh operation using the additional data or the adjusted data characteristics to improve the data integrity of the data.

FIG. 2 illustrates an example of a system 200 that supports data integrity

improvement programming techniques in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230) may communicate with memory devices 240) directly or via a bus (not shown), which may include using a protocol specific to each type of memory device 240). In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230) may support translating data between the host system 205 and the memory devices 240) (e.g., as shown by a data path 250)), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

A temporary storage of data within a buffer 225 may refer to the storage of data in the buffer 225 during the execution of access commands. For example, after completion of an access command, the associated data may no longer be maintained in the buffer 225 (e.g., may be overwritten with data for additional access commands). In some examples, the buffer 225 may be a non-cache buffer. For example, data may not be read directly from the buffer 225 by the host system 205. In some examples, read commands may be added to a queue without an operation to match the address to addresses already in the buffer 225 (e.g., without a cache address match or lookup operation).

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240 and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. For example, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from the buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

In some cases, a storage queue 270 may support a transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain (e.g., from the buffer 225, from the buffer queue 265, from the storage queue 270) the location within the buffer 225 from which to obtain the data. The storage controller 230 may manage the locations within the memory devices 240 to store the data (e.g., performing wear-leveling, performing garbage collection). The entries may be added to the storage queue 270 (e.g., by the memory system controller 215). The entries may be removed from the storage queue 270 (e.g., by the storage controller 230, by the memory system controller 215) after completion of the transfer of the data.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) when the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

Once the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

In accordance with examples as described herein, data integrity improvement programming techniques may be applied to the memory system 210 to improve data integrity of a portion of data otherwise associated with reduced data integrity. For example, data may be programmed to the memory system 210 and the portion of the data associated with reduced data integrity may be identified. In some implementations, additional data may be programmed to the memory system 210 to improve the data integrity of the portion of the data. In other implementations, data characteristics associated with refreshing the data (e.g., read thresholds, voltage threshold levels) may be adjusted to improve the data integrity of the portion of the data. After programming the additional data or adjusting the data characteristics, the memory system 210 may perform a refresh operation using the additional data or the adjusted data characteristics to improve the data integrity of the data.

FIG. 3 illustrates an example of a system 300 that supports data integrity improvement programming techniques in accordance with examples as disclosed herein. The system 300 may be an example of and implement aspects of a system 100 or a system 200, as described with reference to FIGS. 1 and 2, respectively. For example, the system 300 may include a host system 305 and a memory system 310, which may be examples of a host system 105, 205 and a memory system 110, 210 as described with reference to FIGS. 1 and 2, respectively. In some cases, data of the memory system 310 with reduced data integrity may be identified and bolstered to improve data integrity during a refresh operation. Implementing data integrity improvement programming techniques as described herein may reduce or prevent read and refresh performance issues otherwise associated with performing a read or refresh operation on data with reduced data integrity.

The system 300 may include the host system 305 and the memory system 310. where the memory system 310 may include a memory system controller 315 (e.g., a memory system controller 115, 215). In some cases, the memory system controller 315 may facilitate communication between the host system 305 and the memory system 310, and may perform operations (e.g., access operations, refresh operations) on the memory system 310 in accordance with commands (e.g., access commands) from the host system 305 or as determined by the memory system 310 (e.g., for refresh operations). The memory system 310 may include a memory array 320, which may be one of one or more memory arrays associated with one or more non-volatile memory devices (e.g., NAND memory dies). The memory array 320 may include a quantity of blocks 325 (e.g., n blocks, where n may be a positive integer), which may be examples of blocks 170 as described with reference to FIG. 1. In some cases, the blocks 325 may be associated with memory blocks, super-blocks (e.g., subsets of adjacent blocks), or super-block regions (e.g., sets of adjacent super-blocks) of the memory system 310.

In some cases, the memory system 310 may be pre-programmed with data prior to assembling the system 300. For example, a set of blocks 325 (e.g., blocks 325-a, 325-b, 325-c, 325-d) of the memory system 310 may be pre-programmed with user data (e.g., first data) before the memory system 310 is subjected to one or more manufacturing operations. In some examples. pre-programming the memory system 310 may include programming a subset of blocks 325 (e.g., blocks 325-e, 325-f) with metadata associated with the user data. The metadata may aid in bolstering the integrity of the user data by indicating pre-program conditions (e.g., temperatures) associated with performing the one or more manufacturing operations. In some cases, the metadata may indicate pre-program conditions (e.g., temperature) associated with pre-programming the memory system 310 with user data. For example, temperature may vary while pre-programming the user data due to self-heating, testing operations, or assembling operations for preparing the memory system 310 for the one or more manufacturing operations.

In some cases, the one or more manufacturing operations may include processes associated with forming an end-product (e.g., system 300, a printed circuit board (PCB) in a product, such as a handset). For example, forming an end-product may include coupling (e.g., attaching) the memory system 310 with host system 305 on a printed wiring board (PWB) after pre-programming the memory system 310. For example, the one or more operations may include reflow soldering (e.g., reflowing) the memory system 310 to the PWB. In some instances, reflowing the memory system 310 to the PWB may include preheating the memory system 310, the PWB, and solder, then melting the solder at a joint coupling the memory system 310 with the PWB. In some cases, performing the reflowing may subject the memory system 310 to relatively high temperatures, which may adversely affect the data retention capability of blocks 325 (e.g., blocks 325 of the NAND memory dies) of the memory system 310. In some examples, one or more blocks 325 (e.g., blocks 325-c, 325-d) of the memory system 310 may be adversely affected by the relatively high temperatures to a greater extent than other blocks 325 (e.g., blocks 325-a, 325-b, 325-e, 325-f) of the memory system 310, due to a weak geometric layout of word lines associated with the one or more blocks 325.

In some cases, the data integrity of the pre-programmed user data may be adversely affected by the relatively high temperatures associated with performing the reflowing. In some examples, a portion of the pre-programmed user data in the one or more blocks 325 (e.g., blocks 325-c, 325-d) with reduced data retention capability may have reduced data integrity as a result of the relatively high temperatures acting on the one or more blocks 325. In some implementations, a weak geometric layout of word lines associated with accessing the portion of the data may increase the adverse effects of the relatively high temperatures on the portion of the data, thereby further reducing the data integrity of the portion of the data. In some instances, the portion of the pre-programmed user data with reduced data integrity may be lost or corrupted. In some instances, data characteristics associated with the portion of the pre-programmed user data may be adversely affected by the relatively high temperatures acting on the one or more blocks 325. For instance, voltage levels associated with the portion of the pre-programmed user data may be adversely affected (e.g., the voltage levels may shift), altering the ability to perform operations (e.g., access operations, refresh operations) associated with the pre-programmed user data. In such cases, performing an operation (e.g., an access operation, a refresh operation) on the one or more blocks 325 with reduced data retention capability may cause performance issues or failures.

In some cases, the portion of the pre-programmed user data with reduced data integrity may be identified and bolstered to improve the data integrity. For example, the portion of the pre-programmed user data with reduced data integrity may be identified from the one or more blocks 325 (e.g., blocks 325-c, 325-d) associated with the most adversely affected data retention (e.g., from the reflowing), where the portion of the pre-programmed user data is associated with the weakest data integrity of the pre-programmed user data. In some examples, the portion of the pre-programmed user data may be identified and bolstered prior to performing the reflowing or immediately after the reflowing (e.g., prior to in-field). In some examples, the memory system controller 315 or the host system 305 may identify the portion of the pre-programmed user data to be bolstered. In some cases, the metadata pre-programmed to the memory array 320 may be used to identify the portion of the pre-programmed user data to be bolstered based on the metadata including an indication of the pre-program conditions. For example, the metadata may be used to identify which blocks 325 of the memory system 310 are most likely to be affected by the relatively high temperatures of the reflowing.

In some cases, bolstering the portion of the pre-programmed user data may include programming additional data to the memory system 310. For example, the host system 305 may program the additional data to a second subset of blocks 325 (e.g., blocks 325-m, 325-n) of the memory system 310. In some examples, the additional data may be a back-up copy of the pre-programmed user data, where the back-up copy may be verified prior to the programming. In other examples, the additional data may be parity information (e.g., parity bits) associated with the pre-programmed user data, where the parity information may be used to identify and correct errors in the pre-programmed user data. In some implementations, the additional data may be based on the metadata pre-programmed to the memory system 310. For example, the metadata may indicate the portion of the pre-programmed user data likely to have reduced data integrity, and the additional data may be configured based on the metadata.

In other cases, bolstering the portion of the pre-programmed user data may include identifying data characteristics associated with the portion of the pre-programmed user data and performing an operation to adjust the data characteristics. In some implementations, the data characteristics may be adjusted based on the metadata. For example, the metadata may indicate the portion of the pre-programmed user data likely to have reduced data integrity, and the data characteristics may be configured based on the metadata.

In some examples, the data characteristics may be read thresholds (e.g., read trims), where the read thresholds may be associated with thresholds for sensing the pre-programmed user data. In some implementations, the memory system controller 315 or the host system 305 may identify (e.g., via testing) read thresholds (e.g., adjusted read thresholds) to improve the data integrity of the portion of the pre-programmed user data and store the adjusted read thresholds to one or more blocks (e.g., blocks 325-m, 325-n) of the memory system 310. For example, the read thresholds may be adjusted to lower or higher values to sense the portion of the pre-programmed user data with reduced data integrity.

In other examples, the data characteristics may be voltage levels, where the voltage levels may be associated with the distribution of voltage stored to the memory cells of the one or more blocks 325 associated with storing the portion of pre-programmed user data with reduced data integrity. In some implementations, the memory system controller 315 or the host system 305 may perform an additional programming operation (e.g., partial programming) to adjust the voltage levels associated with the portion of the pre-programmed user data with reduced data integrity to improve the data integrity of the portion of the pre-programmed user data. For example, performing the additional programming operation may include programming select memory cells to push the memory cells into the correct voltage distribution level.

In some cases, the memory system 310 will perform a refresh operation after the reflowing. However, in some examples, performing the refresh operation immediately after the reflowing (e.g., in-factory) may cause increased manufacturing time and associated costs. Therefore, the memory system 310 may be refreshed at a later time (e.g., in-field). For example, the memory system 310 may identify an indication during a start-up procedure, where the indication may indicate the memory system 310 to perform the refresh operation. However, the duration between the reflowing and performing the refresh operation may exacerbate the adverse effects of the reflowing. Therefore, the memory system 310 may use the bolstering of the portion of the pre-programmed user data during the refresh operation at the later time. For example, the portion of the pre-programmed user data may be refreshed using the additional data programmed during the bolstering of the portion of the pre-programmed user data. In another example, the portion of the pre-programmed user data may be refreshed using the data characteristics adjusted during the bolstering of the portion of the pre-programmed user data. In such examples, the memory system 310 may benefit from the bolstering with improved data integrity for the portion of the pre-programmed user data otherwise associated with weak data integrity. In some cases, performing the data integrity improvement programming techniques described herein may be associated with improved read and refresh performance, and improved data integrity of the pre-programmed user data.

FIG. 4 illustrates an example of a process flow 400 that supports data integrity improvement programming techniques in accordance with examples as disclosed herein. The process flow: 400 may illustrate aspects or operations of systems 100, 200, or 300, as described with reference to FIGS. 1 through 3, respectively. For example, the process flow 400 may depict operations at a memory system or a host system, which may be examples of a memory system 110, 210, 310 and a host system 105, 205, 305, respectively, as described with reference to FIGS. 1 through 3. In the following description of the process flow 400, the methods, techniques, processes, and operations may be performed in different orders or at different times. Further, certain operations may be left out of the process flow 400, or other operations may be added to the process flow 400. The operations described herein may bolster the integrity of pre-programmed user data in the memory system associated with reduced data integrity, thereby enabling the memory system to perform a refresh operation to improve data integrity of the pre-programmed user data.

Aspects of the process flow 400 may be implemented by a controller (e.g., a memory system controller) which may be an example of memory system controller 115, 215, or 315, as described with reference to FIGS. 1 through 3, respectively. Additionally, or alternatively, aspects of the process flow 400 may be implemented as instructions stored in memory (e.g., firmware stored in a memory coupled with a memory system or a host system). For example, the instructions, when executed by a controller (e.g., the memory system or host system), may cause the controller to perform the operations of the process flow 400.

At 405, data may be pre-programmed to the memory system. For example, the memory system may be configured to a pre-program state, such that the memory system may accept data. In some examples, user data (e.g., BIOS or configuration data) may be pre-programmed to the memory system. In some implementations, metadata may be programmed to the memory system, where the metadata may include an indication of pre-program conditions (e.g., temperatures) associated with assembling the memory system and may aid in bolstering the integrity of the user data. In some examples, pre-programming the data to the memory system may include programming the data to a set of blocks of the memory system, where the blocks may be examples of memory blocks, super blocks, or super block regions of the memory system. In some implementations, the blocks may be examples of blocks 325, as described with reference to FIG. 3.

At 410, the host system or the controller of the memory system may set a flag for refreshing the data pre-programmed to the memory system. For example, the host system may set a flag indicating the memory system to refresh the user data after a start-up procedure, where the start-up procedure may be at a time after assembling the memory system. In some cases, the flag may not be set, such that the memory system may not be instructed to refresh the data pre-programmed during the start-up procedure.

At 415, the memory system may be assembled using one or more manufacturing operations. The one or more manufacturing operations may include processes associated with forming an end-product, which may include coupling the memory system with a PWB after pre-programming the memory system. For example, the one or more manufacturing operations may include reflow soldering (e.g., reflowing) the memory system to the PWB. In some cases, performing the reflowing may subject the memory system to relatively high temperatures, which may adversely affect the data retention capability of one or more blocks of the memory system. In some cases, the data integrity of the pre-programmed user data may be adversely affected by the relatively high temperatures associated with performing the reflowing, resulting in data loss or performance issues. In some instances, data characteristics associated with the pre-programmed user data may be adversely affected by the relatively high temperatures associated with performing the reflowing.

At 420, a portion of the pre-programmed user data with reduced data integrity (e.g., due to the relatively high temperatures associated with reflowing) may be identified and bolstered. For example, one or more blocks associated with reduced data retention may be identified and the portion of the user data pre-programmed to the one or more blocks may be identified. In some cases, bolstering the portion of the pre-programmed user data may include programming additional data to the memory system, where the additional data may be a back-up copy of the user data (e.g., the portion of the pre-programmed user data) or parity information associated with the user data (e.g., the portion of the pre-programmed user data). In some cases, data characteristics associated with the portion of the pre-programmed user data may be identified and adjusted to bolster the integrity of the portion of the pre-programmed user data. For example, the read thresholds associated with the portion of the pre-programmed user data may be adjusted to improve data integrity and then stored in the memory system. In another example, the voltage levels associated with the portion of the pre-programmed user data may be partially programmed to correct the voltage distributions, thereby improving data integrity. In some cases, the metadata pre-programmed to the memory system may be used to bolster the data integrity of the portion of the pre-programmed user data. In some cases, the portion of the pre-programmed user data may be bolstered prior to assembling the memory system at 415.

At 425, the memory system may perform a start-up procedure, where the memory system may determine whether the flag was set to indicate the memory system to perform the refresh on the pre-programmed user data. In some cases, the memory system may identify during the start-up procedure that the flag was set and the memory system may proceed to refresh the pre-programmed user data at 430. However, in other cases, the memory system may identify during the start-up procedure that the flag was not set and the memory system may not refresh the pre-programmed user data at 430.

At 430, the memory system may refresh (e.g., in-field refresh) the pre-programmed user data using the bolstering of the pre-programmed user data. In some cases, the memory system may refresh the portion of the pre-programmed user data using the additional data (e.g., the back-up copy or the parity information). In other cases, the memory system may refresh the portion of the pre-programmed user data using the adjusted data characteristics (e.g., the adjusted read thresholds or the adjusted voltage levels). Refreshing the portion of the pre-programmed user data associated with reduced data integrity using the bolstering techniques (e.g., additional data, adjusted data characteristics) may improve the data integrity of the portion of the pre-programmed user data. In some cases, refreshing the pre-programmed user data using the bolstering techniques may additionally increase the performance of the memory system when performing access operations or reduce data loss, while preventing increased manufacturing time and costs otherwise associated with performing a refresh on the pre-programmed user data immediately after assembling the memory system (e.g., in-factory refresh).

FIG. 5 shows a block diagram 500 of a memory system 520 that supports data integrity improvement programming techniques in accordance with examples as disclosed herein. The memory system 520 may be an example of aspects of a memory system as described with reference to FIGS. 1 through 4. The memory system 520, or various components thereof, may be an example of means for performing various aspects of data integrity improvement programming techniques as described herein. For example, the memory system 520 may include a programming component 525, an identifying component 530, a refresh component 535, a data characteristic component 540), a storing component 545, a determining component 550, or any combination thereof. Each of these components may communicate, directly or indirectly, with one another (e.g., via one or more buses).

The programming component 525 may be configured as or otherwise support a means for programming first data to a first set of blocks of a memory system. In some examples, the programming component 525 may be configured as or otherwise support a means for programming second data to a second set of blocks of the memory system based at least in part on identifying that at least a portion of the first data is associated with reduced data integrity. The identifying component 530 may be configured as or otherwise support a means for identifying. during a start-up procedure, an indication to perform a refresh operation for the first set of blocks. The refresh component 535 may be configured as or otherwise support a means for performing the refresh operation for the first set of blocks based at least in part on the second data in the second set of blocks.

In some examples, the storing component 545 may be configured as or otherwise support a means for storing metadata associated with the first data, where the second data is based at least in part on the metadata.

In some examples, the second data is associated with improving the reduced data integrity of the at least portion of the first data.

In some examples, the second data includes a backup copy of the first data.

In some examples, the second data includes parity bits associated with the first data.

In some examples, the at least portion of the first data is associated with the reduced data integrity based at least in part on word lines associated with accessing a subset of the first set of blocks, the subset of the first set of blocks associated with storing the at least portion of the first data.

In some examples, the word lines are associated with the reduced data integrity based at least in part on a location or a geometric layout of the word lines in the memory system.

In some examples, the first data includes user data.

In some examples, to support identifying that at least the portion of the first data is associated with the reduced data integrity, the determining component 550 may be configured as or otherwise support a means for determining that the at least portion of the first data is associated with the weakest data integrity of the first data.

In some examples, the at least the portion of the first data is associated with the reduced data integrity based at least in part on a temperature of at least a portion of the memory system during the programming of the first data. In some examples, the temperature is associated with causing a reduced data retention for a subset of the first set of blocks storing the at least portion of the first data.

In some examples, the programming component 525 may be configured as or otherwise support a means for programming data to a set of blocks of a memory system. The data characteristic component 540 may be configured as or otherwise support a means for identifying data characteristics associated with at least a portion of the data based at least in part on identifying that the at least the portion of the data is associated with reduced data integrity. In some examples, the data characteristic component 540 may be configured as or otherwise support a means for performing an operation to adjust the data characteristics to improve the data integrity of the at least the portion of the data based at least in part on identifying the data characteristics. In some examples, the identifying component 530 may be configured as or otherwise support a means for identifying, during a start-up procedure, an indication to perform a refresh operation for the set of blocks. In some examples, the refresh component 535 may be configured as or otherwise support a means for performing the refresh operation for the set of blocks using the adjusted data characteristics.

In some examples, the storing component 545 may be configured as or otherwise support a means for storing metadata associated with the data, where the data characteristics are based at least in part on the metadata.

In some examples, to support performing the operation to adjust the data characteristics, the data characteristic component 540 may be configured as or otherwise support a means for identifying adjusted read thresholds to improve the data integrity of the at least portion of the data. In some examples, to support performing the operation to adjust the data characteristics, the storing component 545 may be configured as or otherwise support a means for storing the adjusted read thresholds.

In some examples, to support performing the operation to adjust the data characteristics, the data characteristic component 540 may be configured as or otherwise support a means for performing a programming operation to adjust the voltage levels associated with the at least the portion of the data to improve the data integrity of the at least the portion of the data.

In some examples, the at least the portion of the data is associated with the reduced data integrity based at least in part on word lines associated with accessing a subset of the first set of blocks, the subset of the first set of blocks associated with storing the at least the portion of the data.

In some examples, the word lines are associated with the reduced data integrity based at least in part on a location or a geometric layout of the word lines in the memory system.

In some examples, the data includes user data.

In some examples, to support identifying that the at least the portion of the data is associated with the reduced data integrity, the determining component 550 may be configured as or otherwise support a means for determining that the at least the portion of the data is associated with the weakest data integrity of the data.

In some examples, the at least the portion of the data is associated with the reduced data integrity based at least in part on a temperature of at least a portion of the memory system during the programming of the data. In some examples, the temperature is associated with causing a reduced data retention for a subset of the first set of blocks storing the at least portion of the first data.

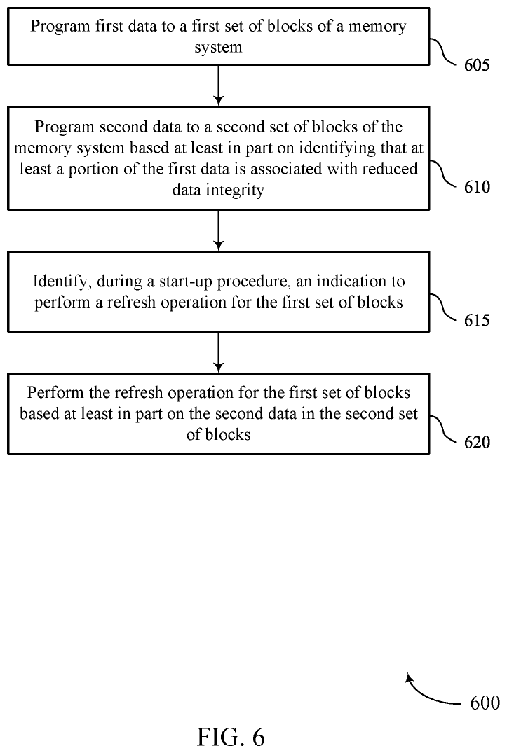

FIG. 6 shows a flowchart illustrating a method 600 that supports data integrity improvement programming techniques in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include programming first data to a first set of blocks of a memory system. The operations of 605 may be performed in accordance with examples as disclosed herein. In some examples, aspects of the operations of 605 may be performed by a programming component 525 as described with reference to FIG. 5.

At 610, the method may include programming second data to a second set of blocks of the memory system based at least in part on identifying that at least a portion of the first data is associated with reduced data integrity. The operations of 610 may be performed in accordance with examples as disclosed herein. In some examples, aspects of the operations of 610 may be performed by a programming component 525 as described with reference to FIG. 5.

At 615, the method may include identifying, during a start-up procedure, an indication to perform a refresh operation for the first set of blocks. The operations of 615 may be performed in accordance with examples as disclosed herein. In some examples, aspects of the operations of 615 may be performed by an identifying component 530 as described with reference to FIG. 5.

At 620, the method may include performing the refresh operation for the first set of blocks based at least in part on the second data in the second set of blocks. The operations of 620 may be performed in accordance with examples as disclosed herein. In some examples, aspects of the operations of 620 may be performed by a refresh component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for programming first data to a first set of blocks of a memory system; programming second data to a second set of blocks of the memory system based at least in part on identifying that at least a portion of the first data is associated with reduced data integrity; identifying, during a start-up procedure, an indication to perform a refresh operation for the first set of blocks; and performing the refresh operation for the first set of blocks based at least in part on the second data in the second set of blocks.

Aspect 2: The method, apparatus, or non-transitory computer-readable medium of aspect 1, further including operations, features, circuitry, logic, means, or instructions, or any combination thereof for storing metadata associated with the first data, where the second data is based at least in part on the metadata.

Aspect 3: The method, apparatus, or non-transitory computer-readable medium of any of aspects 1 through 2, where the second data is associated with improving the reduced data integrity of the at least portion of the first data.

Aspect 4: The method, apparatus, or non-transitory computer-readable medium of any of aspects 1 through 3, where the second data includes a backup copy of the first data.

Aspect 5: The method, apparatus, or non-transitory computer-readable medium of any of aspects 1 through 4, where the second data includes parity bits associated with the first data.

Aspect 6: The method, apparatus, or non-transitory computer-readable medium of any of aspects 1 through 5, where the at least portion of the first data is associated with the reduced data integrity based at least in part on word lines associated with accessing a subset of the first set of blocks, the subset of the first set of blocks associated with storing the at least portion of the first data.

Aspect 7: The method, apparatus, or non-transitory computer-readable medium of aspect 6, where the word lines are associated with the reduced data integrity based at least in part on a location or a geometric layout of the word lines in the memory system.

Aspect 8: The method, apparatus, or non-transitory computer-readable medium of any of aspects 1 through 7, where the first data includes user data.

Aspect 9: The method, apparatus, or non-transitory computer-readable medium of any of aspects 1 through 8, where the identifying that at least the portion of the first data is associated with the reduced data integrity includes operations, features, circuitry, logic, means, or instructions, or any combination thereof for determining that the at least portion of the first data is associated with the weakest data integrity of the first data.

Aspect 10: The method, apparatus, or non-transitory computer-readable medium of any of aspects 1 through 9, where the at least the portion of the first data is associated with the reduced data integrity based at least in part on a temperature of at least a portion of the memory system during the programming of the first data and the temperature is associated with causing a reduced data retention for a subset of the first set of blocks storing the at least portion of the first data.

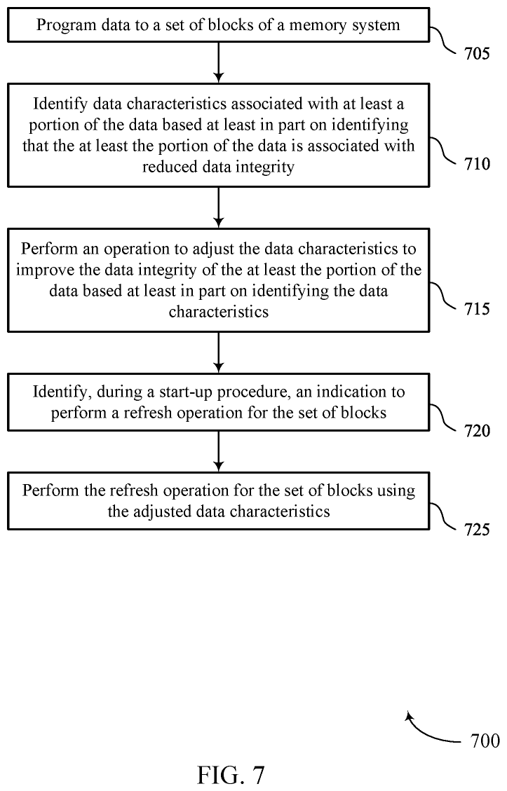

FIG. 7 shows a flowchart illustrating a method 700 that supports data integrity improvement programming techniques in accordance with examples as disclosed herein. The operations of method 700 may be implemented by a memory system or its components as described herein. For example, the operations of method 700 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 705, the method may include programming data to a set of blocks of a memory system. The operations of 705 may be performed in accordance with examples as disclosed herein. In some examples, aspects of the operations of 705 may be performed by a programming component 525 as described with reference to FIG. 5.

At 710, the method may include identifying data characteristics associated with at least a portion of the data based at least in part on identifying that the at least the portion of the data is associated with reduced data integrity. The operations of 710 may be performed in accordance with examples as disclosed herein. In some examples, aspects of the operations of 710 may be performed by a data characteristic component 540 as described with reference to FIG. 5.

At 715, the method may include performing an operation to adjust the data characteristics to improve the data integrity of the at least the portion of the data based at least in part on identifying the data characteristics. The operations of 715 may be performed in accordance with examples as disclosed herein. In some examples, aspects of the operations of 715 may be performed by a data characteristic component 540 as described with reference to FIG. 5.

At 720, the method may include identifying, during a start-up procedure, an indication to perform a refresh operation for the set of blocks. The operations of 720 may be performed in accordance with examples as disclosed herein. In some examples, aspects of the operations of 720 may be performed by an identifying component 530 as described with reference to FIG. 5.

At 725, the method may include performing the refresh operation for the set of blocks using the adjusted data characteristics. The operations of 725 may be performed in accordance with examples as disclosed herein. In some examples, aspects of the operations of 725 may be performed by a refresh component 535 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 11: A method, apparatus, or non-transitory computer-readable medium including operations, features, circuitry, logic, means, or instructions, or any combination thereof for programming data to a set of blocks of a memory system; identifying data characteristics associated with at least a portion of the data based at least in part on identifying that the at least the portion of the data is associated with reduced data integrity; performing an operation to adjust the data characteristics to improve the data integrity of the at least the portion of the data based at least in part on identifying the data characteristics; identifying, during a start-up procedure, an indication to perform a refresh operation for the set of blocks; and performing the refresh operation for the set of blocks using the adjusted data characteristics.

Aspect 12: The method, apparatus, or non-transitory computer-readable medium of aspect 11, further including operations, features, circuitry, logic, means, or instructions, or any combination thereof for storing metadata associated with the data, where the data characteristics are based at least in part on the metadata.

Aspect 13: The method, apparatus, or non-transitory computer-readable medium of any of aspects 11 through 12, where performing the operation to adjust the data characteristics includes operations, features, circuitry, logic, means, or instructions, or any combination thereof for identifying adjusted read thresholds to improve the data integrity of the at least portion of the data and storing the adjusted read thresholds.

Aspect 14: The method, apparatus, or non-transitory computer-readable medium of any of aspects 11 through 13, where performing the operation to adjust the data characteristics includes operations, features, circuitry, logic, means, or instructions, or any combination thereof for performing a programming operation to adjust the voltage levels associated with the at least the portion of the data to improve the data integrity of the at least the portion of the data.

Aspect 15: The method, apparatus, or non-transitory computer-readable medium of any of aspects 11 through 14, where the at least the portion of the data is associated with the reduced data integrity based at least in part on word lines associated with accessing a subset of the first set of blocks, the subset of the first set of blocks associated with storing the at least the portion of the data.

Aspect 16: The method, apparatus, or non-transitory computer-readable medium of aspect 15, where the word lines are associated with the reduced data integrity based at least in part on a location or a geometric layout of the word lines in the memory system.

Aspect 17: The method, apparatus, or non-transitory computer-readable medium of any of aspects 11 through 16, where the data includes user data.

Aspect 18: The method, apparatus, or non-transitory computer-readable medium of any of aspects 11 through 17, where the identifying that the at least the portion of the data is associated with the reduced data integrity includes operations, features, circuitry, logic, means, or instructions, or any combination thereof for determining that the at least the portion of the data is associated with the weakest data integrity of the data.

Aspect 19: The method, apparatus, or non-transitory computer-readable medium of any of aspects 11 through 18, where the at least the portion of the data is associated with the reduced data integrity based at least in part on a temperature of at least a portion of the memory system during the programming of the data and the temperature is associated with causing a reduced data retention for a subset of the first set of blocks storing the at least portion of the first data.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
programming first data to a first set of blocks of a memory system;
programming second data to a second set of blocks of the memory system based at least in part on identifying that at least a portion of the first data is associated with reduced data integrity;
identifying, during a start-up procedure, an indication to perform a refresh operation for the first set of blocks; and
performing the refresh operation for the first set of blocks based at least in part on the second data in the second set of blocks.

2. The method of claim 1, further comprising:
storing metadata associated with the first data, wherein the second data is based at least in part on the metadata.

3. The method of claim 1, wherein the second data is associated with improving the reduced data integrity of the at least portion of the first data.

4. The method of claim 1, wherein the second data comprises a backup copy of the first data.

5. The method of claim 1, wherein the second data comprises parity bits associated with the first data.

6. The method of claim 1, wherein the at least portion of the first data is associated with the reduced data integrity based at least in part on word lines associated with accessing a subset of the first set of blocks, the subset of the first set of blocks associated with storing the at least portion of the first data.

7. The method of claim 6, wherein the word lines are associated with the reduced data integrity based at least in part on a location or a geometric layout of the word lines in the memory system.

8. The method of claim 1, wherein the first data comprises user data.

9. The method of claim 1, wherein the identifying that at least the portion of the first data is associated with the reduced data integrity comprises:
determining that the at least portion of the first data is associated with the weakest data integrity of the first data.

10. The method of claim 1, wherein
the at least the portion of the first data is associated with the reduced data integrity based at least in part on a temperature of at least a portion of the memory system during the programming of the first data,
the temperature is associated with causing a reduced data retention for a subset of the first set of blocks storing the at least portion of the first data.

11. A method, comprising:
programming data to a set of blocks of a memory system;
identifying data characteristics associated with at least a portion of the data based at least in part on identifying that the at least the portion of the data is associated with reduced data integrity;
performing an operation to adjust the data characteristics to improve the data integrity of the at least the portion of the data based at least in part on identifying the data characteristics;
identifying, during a start-up procedure, an indication to perform a refresh operation for the set of blocks; and
performing the refresh operation for the set of blocks using the adjusted data characteristics.

12. The method of claim 11, further comprising:
storing metadata associated with the data, wherein the data characteristics are based at least in part on the metadata.

13. The method of claim 11, wherein the data characteristics comprise read thresholds associated with the data, and wherein performing the operation to adjust the data characteristics comprises:
identifying adjusted read thresholds to improve the data integrity of the at least portion of the data; and
storing the adjusted read thresholds.

14. The method of claim 11, wherein the data characteristics comprise voltage levels associated with the data, and wherein performing the operation to adjust the data characteristics comprises:
performing a programming operation to adjust the voltage levels associated with the at least the portion of the data to improve the data integrity of the at least the portion of the data.

15. The method of claim 11, wherein the at least the portion of the data is associated with the reduced data integrity based at least in part on word lines associated with accessing a subset of the first set of blocks, the subset of the first set of blocks associated with storing the at least the portion of the data.

16. The method of claim 15, wherein the word lines are associated with the reduced data integrity based at least in part on a location or a geometric layout of the word lines in the memory system.

17. The method of claim 11, wherein the data comprises user data.

18. The method of claim 11, wherein the identifying that the at least the portion of the data is associated with the reduced data integrity comprises:
determining that the at least the portion of the data is associated with the weakest data integrity of the data.

19. The method of claim 11, wherein
the at least the portion of the data is associated with the reduced data integrity based at least in part on a temperature of at least a portion of the memory system during the programming of the data,
the temperature is associated with causing a reduced data retention for a subset of the first set of blocks storing the at least portion of the first data.

20. A non-transitory computer-readable medium storing code, the code comprising instructions executable by a processor to:
program first data to a first set of blocks of a memory system;
program second data to a second set of blocks of the memory system based at least in part on identifying that at least a portion of the first data is associated with reduced data integrity;
identify, during a start-up procedure, an indication to perform a refresh operation for the first set of blocks; and
perform the refresh operation for the first set of blocks based at least in part on the second data in the second set of blocks.

21. The non-transitory computer-readable medium of claim 20, wherein the instructions are further executable by the processor to:
store metadata associated with the first data, wherein the second data is based at least in part on the metadata, and wherein the second data is associated with improving the reduced data integrity of the at least portion of the first data.

22. The non-transitory computer-readable medium of claim 20, wherein the second data comprises a backup copy of the first data or parity bits associated with the first data.

23. A non-transitory computer-readable medium storing code, the code comprising instructions executable by a processor to:
program data to a set of blocks of a memory system;
identify data characteristics associated with at least a portion of the data based at least in part on identifying that the at least the portion of the data is associated with reduced data integrity;
perform an operation to adjust the data characteristics to improve the data integrity of the at least the portion of the data based at least in part on identifying the data characteristics;
identify, during a start-up procedure, an indication to perform a refresh operation for the set of blocks; and
perform the refresh operation for the set of blocks using the adjusted data characteristics.

24. The non-transitory computer-readable medium of claim 23, wherein the instructions to perform the operation to adjust the data characteristics are executable by the processor to:
identify adjusted read thresholds to improve the data integrity of the at least portion of the data; and
store the adjusted read thresholds.

25. The non-transitory computer-readable medium of claim 23, wherein the instructions to perform the operation to adjust the data characteristics are executable by the processor to:
perform a programming operation to adjust the voltage levels associated with the at least the portion of the data to improve the data integrity of the at least the portion of the data.
